(19) United States
(12) Patent Application Publication
(10) Pub. No.: US 2015/0348871 A1
(43) Pub. Date: Dec. 3, 2015

(54) SEMICONDUCTOR DEVICE AND METHOD FOR MANUFACTURING THE SAME

(71) Applicant: INOTERA MEMORIES, INC., Taoyuan (TW)

(72) Inventors: Hsu Chiang, New Taipei City (TW); Yaw-Wen Hu, Taoyuan County (TW); Neng-Tai Shih, New Taipei City (TW); Tzung-Han Lee, Taipei City (TW)

(73) Assignee: INOTERA MEMORIES, INC., Taoyuan (TW)

(21) Appl. No.: 14/289,664

(22) Filed: May 29, 2014

(51) Int. Cl. H01L 23/48; H01L 23/50

(52) U.S. Cl. CPC H01L 23/481; H01L 23/50

(57) ABSTRACT

A semiconductor device includes a substrate having a first side and a second side opposite to the first side; a through substrate via (TSV) structure protruding from a surface of the substrate on the second side; a block layer conformally covering the surface of the substrate and the TSV structure; a first dielectric layer covering the block layer except for a portion of the block layer that is directly on the TSV structure; a second dielectric layer on the first dielectric layer; and a damascened circuit pattern in the second dielectric layer. The second dielectric layer is in direct contact with the first dielectric layer. The damascened circuit pattern is in direct contact with the TSV structure.

### BACKGROUND OF THE INVENTION

1. Field of the Invention

The present invention relates generally to a semiconductor device and a method for manufacturing the same. More particularly, the present invention relates to

2. Description of the Prior Art

Three dimensional (3D) integrated circuits utilizing through silicon via (TSV) structures have become popular these years as driven by the strong demand for high speed, high density, small size, and multifunctional electronic devices. The TSV structures are via openings that extend completely through a semiconductor substrate and enable devices above and below the substrate to be coupled to one another and to devices internal to the substrate.

To address the needs in flip chip packaging technology, silicon interposer with TSV has emerged as a good solution to provide high density interconnection, minimize coefficient of thermal expansion (CTE) mismatch between the die and the interposer, and improve electrical performance due to short interconnection from chip to the substrate.

However, the prior art has some drawbacks. For example, to control copper/oxide protrusion and copper-silicon contamination, a block layer is typically deposited after the CMP step for polishing the TSV oxide. This additional block layer causes delamination and reliability issues after packaging.

### SUMMARY OF THE INVENTION

One object of the present invention is to provide an improved semiconductor device involving a through silicon via (TSV) structure that is capable of avoiding the abovementioned delamination and reliability problems.

According to one embodiment, a semiconductor device includes a substrate having a first side and a second side opposite to the first side; a through substrate via (TSV) structure protruding from a surface of the substrate on the second side; a block layer conformally covering the surface of the substrate and the TSV structure; a first dielectric layer covering the block layer except for a portion of the block layer that is directly on the TSV structure; a second dielectric layer on the first dielectric layer; and a damascened circuit pattern in the second dielectric layer. The second dielectric layer is indirect contact with the first dielectric layer. The damascened circuit pattern is in direct contact with the TSV structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles. In the drawings:

FIGS. 1-5 illustrate an exemplary method for fabricating a semiconductor device according to one embodiment of this invention.

It should be noted that all the figures are diagrammatic. Relative dimensions and proportions of parts of the drawings are exaggerated or reduced in size, for the sake of clarity and convenience. The same reference signs are generally used to refer to corresponding or similar features in modified and different embodiments.

### DETAILED DESCRIPTION

In the following description, numerous specific details are given to provide a thorough understanding of the invention. It will, however, be apparent to one skilled in the art that the invention may be practiced without these specific details. Furthermore, some well-known system configurations and process steps are not disclosed in detail, as these should be well-known to those skilled in the art.

Likewise, the drawings showing embodiments of the apparatus are semi-diagrammatic and not to scale and some dimensions are exaggerated in the figures for clarity of presentation. Also, where multiple embodiments are disclosed and described as having some features in common, like or similar features will usually be described with like reference numerals for ease of illustration and description thereof.

The terms wafer and substrate used herein include any structure having an exposed surface onto which a layer is deposited according to the present invention, for example, to form the integrated circuit (IC) structure. The term substrate is understood to include semiconductor wafers. The term substrate is also used to refer to semiconductor structures during processing, and may include other layers that have been fabricated thereupon. Both wafer and substrate include doped and undoped semiconductors, epitaxial semiconductor layers supported by a base semiconductor or insulator, as well as other semiconductor structures well known to one skilled in the art.

The following detailed description is, therefore, not to be taken in a limiting sense, and the scope of the present invention is defined only by the appended claims, along with the full scope of equivalents to which such claims are entitled.

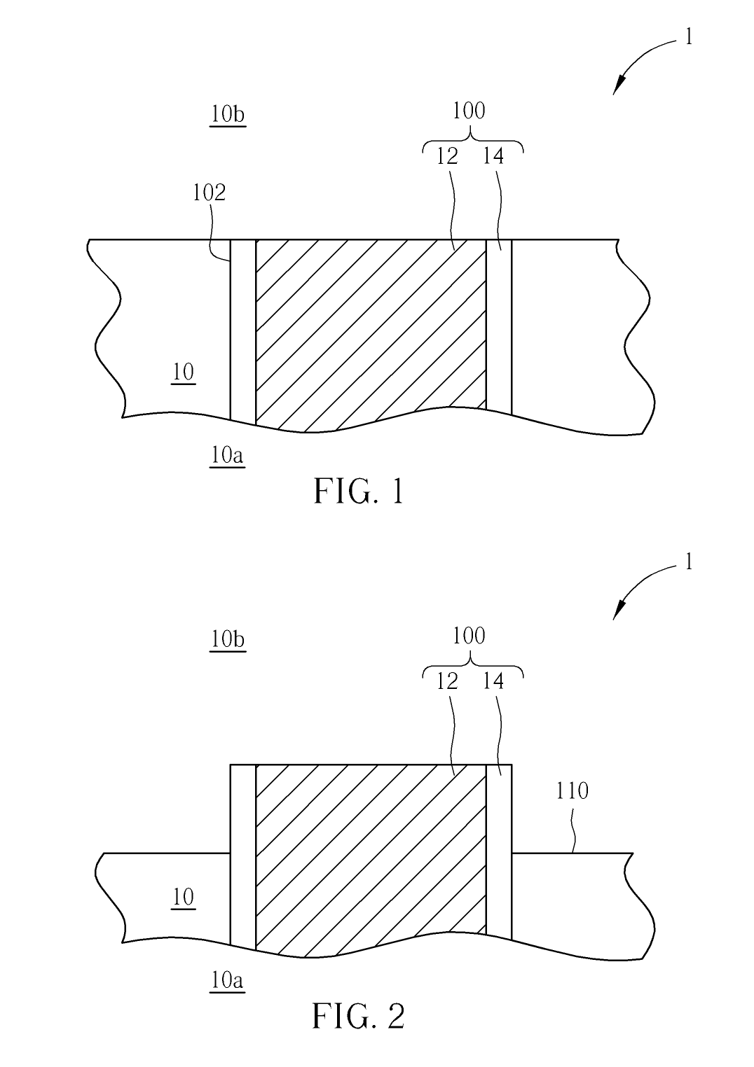

FIGS. 1-5 illustrate an exemplary method for fabricating a semiconductor device 1 according to one embodiment of this invention. As shown in FIG. 1, a substrate 10 such as a silicon substrate is provided. The substrate 10 comprises a first side 10a and a second side 10b that is opposite to the first side 10a. Although not shown in these figures, it is to be understood that a plurality of circuit patterns may be formed on the first side 10a. A through hole 102 is formed in the substrate 10. The through hole 102 may extend through the entire thickness of the substrate 10. A liner layer 14 such as a silicon oxide layer is provided within the through hole 102 to cover the interior surface of the thought hole 102. The through hole 102 is completely filled with a conductive layer 12 such as a copper layer, to thereby form a through substrate via or through silicon via (TSV) structure 100.

As shown in FIG. 2, the substrate 10 is recessed on the second side 10b. For example, the substrate 10 is etched on the second side 10b, leaving the TSV structure 100 intact. After recessing the substrate 10 on the second side 10b, the TSV structure 100 protrudes from a surface 110 of the substrate 10. A portion of the sidewall of the liner layer 14 is exposed.

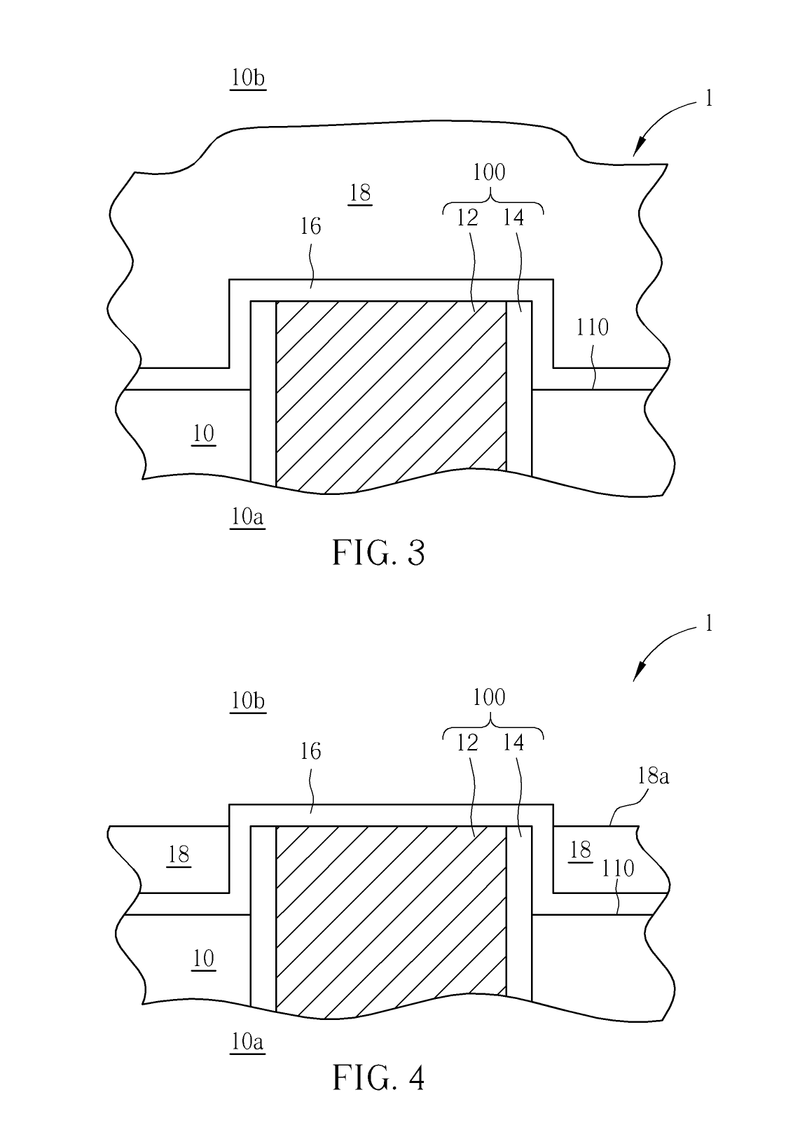

As shown in FIG. 3, after recessing the substrate 10 on the second side 10b, a block layer 16 is conformally deposited on the second side 10b of the substrate 10. The block layer 16 conformally covers the protrudent TSV structure 100 and the surface 110 and is in direct contact with a top surface of the conductive layer 12. According to the embodiment, the block layer 16 may comprise silicon nitride or silicon oxynitride. According to one preferable embodiment, the block layer 16 may comprise silicon nitride that is deposited under 200° C. After the deposition of the block layer 16, a first dielectric layer 18 is deposited on the block layer 16. According to one preferable embodiment, the first dielectric layer 18 may comprise silicon oxide that is deposited under 200° C.

As shown in FIG. 4, subsequently, a chemical mechanical polishing (CMP) process is performed to remove an upper portion of the first dielectric layer 18 until the block layer 16 directly on the conductive layer 12 is exposed. According to one preferable embodiment, the aforesaid CMP process does not remove the block layer 16 due to the high polish selectivity between the block layer 16 and the first dielectric layer 18. Therefore, the conductive layer 12 is unexposed. After the CMP, the first dielectric layer 18 has a polished surface 18a that may be slightly lower than the top surface of the block layer 16 directly on the TSV structure 100.

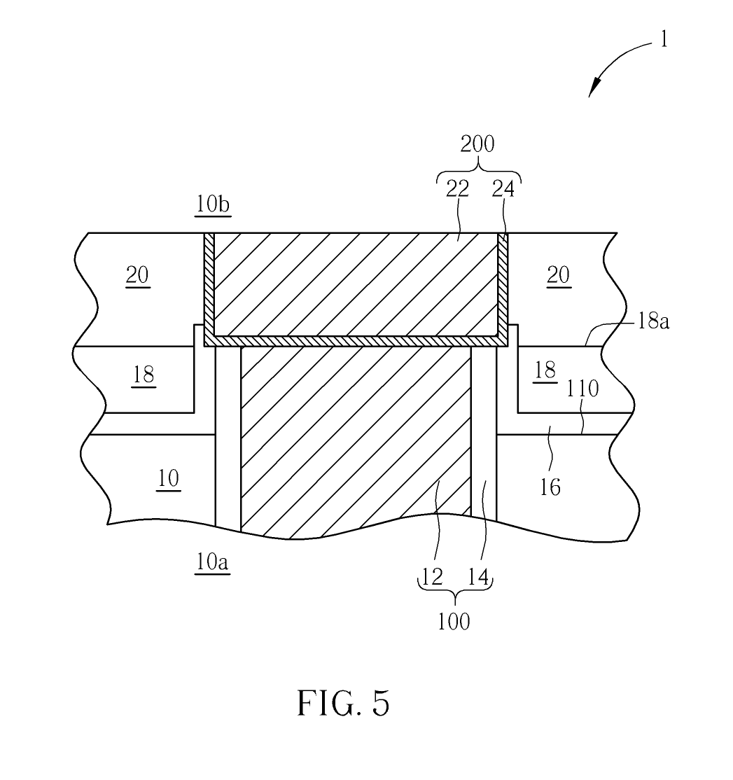

As shown in FIG. 5, a second dielectric layer 20 is deposited on the second side 10b of the substrate 10. According to one preferable embodiment, the second dielectric layer 20 may comprise silicon oxide, but not limited thereto. The second dielectric layer 20 is in direct contact with the first dielectric layer 18. The second dielectric layer 20 is in direct contact with the block layer 16 that is directly on the TSV structure 100. Subsequently, an embedded or damascened circuit structure 200 may be formed in the second dielectric layer 20 and the block layer 16. The circuit structure 200 is in direct contact with the conductive layer 12. According to one preferable embodiment, the circuit structure 200 may comprise a metal layer 22 and a barrier layer 24 between the metal layer 22 and the second dielectric layer 20. According to one preferable embodiment, the metal layer 22 may comprise copper or any suitable metal materials. According to one preferable embodiment, the barrier layer 24 may comprise titanium nitride, tantalum nitride or any suitable barrier materials known in the art. Although only one level of interconnection is shown on the second side 10b to electrically connect the TSV structure 100, it is to be understood that there may be two or more levels of interconnection in other cases depending upon the design requirements. According to one preferable embodiment, the semiconductor device 1 may be an interposer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate having a first side and a second side opposite to the first side;
a through substrate via (TSV) structure protruding from a surface of the substrate on the second side;
a block layer conformally covering the surface of the substrate and the TSV structure;
a first dielectric layer covering the block layer except for a portion of the block layer that is directly on the TSV structure;
a second dielectric layer on the first dielectric layer, wherein the second dielectric layer is in direct contact with the first dielectric layer; and
a damascened circuit pattern in the second dielectric layer, wherein the damascened circuit pattern is in direct contact with the TSV structure.

2. The semiconductor device according to claim 1 wherein the TSV structure comprises a conductive layer and a liner layer between the conductive layer and the substrate.

3. The semiconductor device according to claim 2 wherein the liner layer comprises silicon oxide.

4. The semiconductor device according to claim 2 wherein the conductive layer comprises copper.

5. The semiconductor device according to claim 1 wherein the substrate is a silicon substrate.

6. The semiconductor device according to claim 1 wherein the block layer comprises silicon nitride.

7. The semiconductor device according to claim 1 wherein the first dielectric layer has a polished surface that is slightly lower than a top surface of the portion of the block layer directly on the TSV structure.

8. The semiconductor device according to claim 1 wherein the first dielectric layer comprises silicon oxide.

9. The semiconductor device according to claim 1 wherein the second dielectric layer comprises silicon oxide.

10. The semiconductor device according to claim 1 wherein the damascened circuit pattern comprises a copper layer and a barrier layer surrounding the copper layer.
